(19) United States
(12) Patent Application Publication
(10) Pub. No.: US 2018/0308931 A1
(43) Pub. Date: Oct. 25, 2018

(54) THIN FILM TRANSISTOR, DISPLAY SUBSTRATE, DISPLAY DEVICE, AND MANUFACTURING METHODS THEREOF

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventors: Hefei LI, Beijing (CN); Xianxue DUAN, Beijing (CN); Chengcheng WANG, Beijing (CN); Tianzhen LIU, Beijing (CN)

(73) Assignees: BOE TECHNOLOGY GROUP CO., LTD., Beijing (CN); HEFEI BOE OPTOELECTRONICS TECHNOLOGY CO., LTD., Anhui (CN)

(21) Appl. No.: 15/820,732

(22) Filed: Nov. 22, 2017

(30) Foreign Application Priority Data
Apr. 25, 2017 (CN) 201710276986.9

(51) Int. Cl. H01L 29/06; H01L 29/43; H01L 27/15

(52) U.S. Cl. CPC H01L 29/0657; B82Y 30/00; H01L 27/156; H01L 29/43

(57) ABSTRACT

The present disclosure provides in some embodiments a thin film transistor, a display substrate, a display device and manufacturing methods thereof. The method for manufacturing the thin film transistor includes: forming an active layer having a first groove structure and a second groove structure, the first groove structure and the second groove structure being separated from each other; and depositing a conductive layer into the first groove structure and the second groove structure to form a first electrode and a second electrode of the thin film transistor.

### CROSS-REFERENCE TO RELATED APPLICATION

This application claims priority to Chinese Patent Application No. 201710276986.9 filed on Apr. 25, 2017, which is incorporated herein by reference in its entirety.

### TECHNICAL FIELD

The present disclosure relates to the manufacture of display products, in particular to a thin film transistor (TFT), a display substrate, a display device and manufacturing methods thereof.

### BACKGROUND

Along with the rapid development of TFT-liquid crystal display (TFT-LCD), the display quality, e.g., uniformity of a display image, high resolution and being free of crosstalk, is highly demanded. An off-state current (I_{off}, also called as leakage current) of a TFT is one of the important parameters that may affect the display quality. A switching characteristic of the TFT may be adversely affected by the high off-state current, and thereby such defects as display non-uniformity, being whitish and crosstalk may occur for the TFT-LCD.

For the conventional TFT of a back channel etch (BCE) type, during the manufacture, a silicon island structure of an active layer is formed prior to the formation of a first electrode and a second electrode. During the formation of a channel by etching, the BCE-type TFT may be polluted by metallic ions from the first electrode and the second electrode, so conductivity of the active layer may be adversely affected, the off-state current may be too high, and TFT characteristics may be adversely affected.

### SUMMARY

In one aspect, the present disclosure provides in some embodiments a method for manufacturing a TFT, including steps of: forming an active layer having a first groove structure and a second groove structure, the first groove structure and the second groove structure being separated from each other; and depositing a conductive layer into the first groove structure and the second groove structure to form a first electrode and a second electrode of the TFT.

In a possible embodiment of the present disclosure, the step of forming the active layer having the first groove structure and the second groove structure includes: depositing a semiconductor material layer; applying a photoresist onto the semiconductor material layer; exposing and developing the photoresist with a mask plate to form a photoresist partially-reserved region corresponding to the first groove structure and the second groove structure, a photoresist fully-reserved region corresponding to a region of the active layer other than the first groove structure and the second groove structure, and a photoresist unreserved region corresponding to a region other than a pattern of the active layer; etching the semiconductor material layer at the photoresist unreserved region; ashing the photoresist at the photoresist partially-reserved region, and etching the semiconductor material layer at the photoresist partially-reserved region to form the first groove structure and the second groove structure; and ashing the photoresist at the photoresist fully-reserved region.

In a possible embodiment of the present disclosure, a third groove structure is further arranged at a region corresponding to the photoresist partially-reserved region, and the method further includes forming the third groove structure between the first groove structure and the second groove structure while forming the first groove structure and the second groove structure, the third groove structure being separated from the first groove structure and the second groove structure.

In a possible embodiment of the present disclosure, the step of depositing the conductive material into the first groove structure and the second groove structure includes spraying a metallic nanomaterial solution into the first groove structure and the second groove structure through ink-jet printing to form the first electrode at least partially within the first groove structure and the second electrode at least partially within the second groove structure.

In a possible embodiment of the present disclosure, the metallic nanomaterial solution includes nanoparticles made of one or more selected from the group of Cu, Al, Ag, Mo, Cr, Nd, Ni, Mn, Ti, Ta and W.

In a possible embodiment of the present disclosure, prior to the step of forming the active layer having the first groove structure and the second groove structure, the method further includes forming a gate electrode and a gate insulation layer on a base substrate, and the active layer is formed on the gate insulation layer.

In a possible embodiment of the present disclosure, the first groove structure and the second groove structure are depressed in an identical direction and toward the base substrate.

In another aspect, the present disclosure provides in some embodiments a TFT manufactured by the above-mentioned method, including: an active layer having a first groove structure and a second groove structure, the first groove structure and the second groove structure being separated from each other; and a first electrode at least partially within the first groove structure and a second electrode at least partially within the second groove structure.

In a possible embodiment of the present disclosure, the active layer further includes a third groove structure arranged between, and separated from, the first groove structure and the second groove structure.

In yet another aspect, the present disclosure provides in some embodiments a method for manufacturing a display substrate, including the above-mentioned method for manufacturing the TFT of the display substrate.

In still yet another aspect, the present disclosure provides in some embodiments a display substrate including the above-mentioned TFT.

In still yet another aspect, the present disclosure provides in some embodiments a display device including the above-mentioned display substrate.

### BRIEF DESCRIPTION OF THE DRAWINGS

FIGS. 1A-1H are schematic views showing a TFT according to one embodiment of the present disclosure;

FIG. 2 is a schematic view showing a display substrate according to one embodiment of the present disclosure; and

FIG. 3 is another schematic view showing the display substrate according to one embodiment of the present disclosure; and

FIG. 4 is yet another schematic view showing the display substrate according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

In the related art, conductivity of an active layer may be adversely affected by a method for manufacturing a TFT. In order to solve this problem, the present disclosure provides in some embodiments a method for manufacturing a TFT, including: Step 1 of forming an active layer having a first groove structure and a second groove structure, the first groove structure and the second groove structure being separated from each other; and Step 2 of depositing a conductive layer into the first groove structure and the second groove structure to form a first electrode and a second electrode of the TFT. Here, the first electrode and the second electrode of the TFT may be a source electrode and a drain electrode of the TFT, respectively.

According to the method in the embodiments of the present disclosure, the active layer having the first groove structure and the second groove structure is formed at first. The first groove structure is arranged at a position corresponding to the first electrode and the second groove structure is arranged at a position corresponding to the second electrode. Next, the conductive material is deposited into the first groove structure and the second groove structure to form the first electrode and the second electrode. During the deposition, it is able to effectively prevent the conductive material from being spread to the other regions of the active layer through the first groove structure and the second groove structure, thereby to prevent the conductivity of the other portions of the active layer from being adversely affected by metallic ions of the conductive material and reduce an off-state current of the TFT.

In addition, according to the method in the embodiments of the present disclosure, it is unnecessary to form the first electrode and the second electrode by etching a conductive material layer through an etching process. As compared with a conventional manufacture process, it is able to improve the manufacture efficiency and reduce the manufacture cost.

The method in the embodiments of the present disclosure will be described hereinafter in more details. Here, the TFT may be a bottom-gate or top-gate type, or any other type.

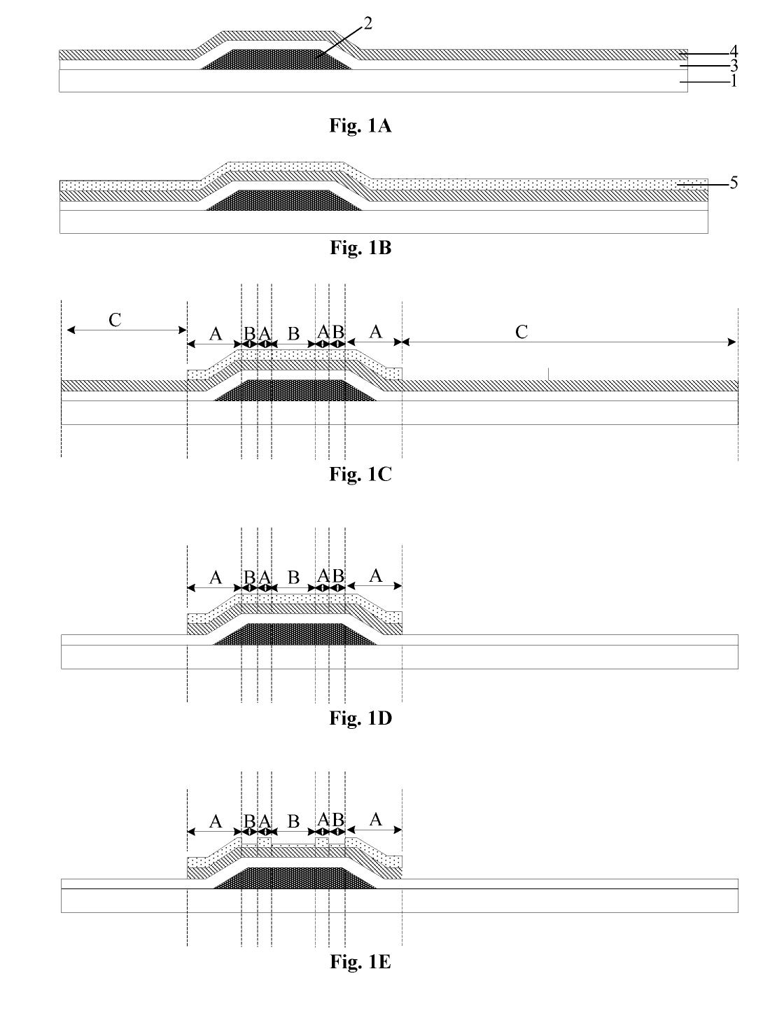

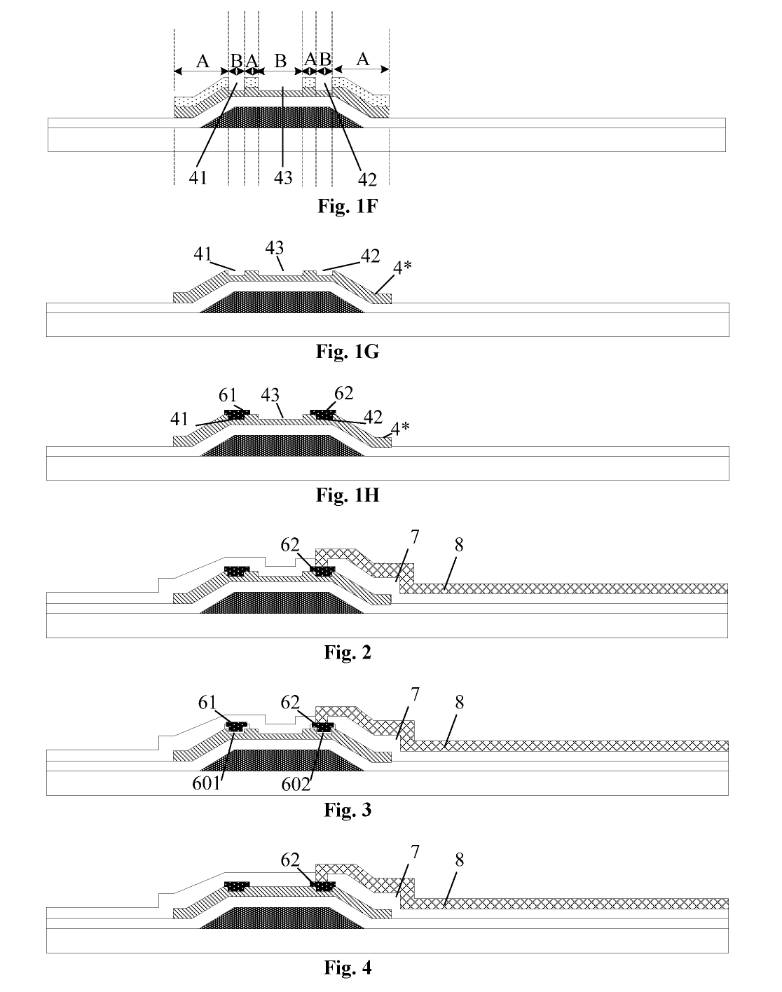

For example, in the case that the TFT is of a bottom-gate type, the method may include the following steps. Step 11: as shown in FIG. 1A, a gate electrode 2, a gate insulation layer 3 and a semiconductor material layer 4 may be formed sequentially on a base substrate 1. Step 12: as shown in FIG. 1B, a photoresist 5 may be applied onto the semiconductor material layer 4 (a positive photoresist is taken as an example in the embodiments of the present disclosure, and it should be appreciated that a negative photoresist may also be applied). Step 13: as shown in FIG. 1C, the photoresist 4 may be exposed and developed with a mask plate to form a photoresist partially-reserved region B corresponding to the first groove structure and the second groove structure (in some embodiments of the present disclosure, one or more other groove structures may be arranged between the first groove structure and the second groove structure, FIG. 1 merely shows a situation where one groove structure is arranged therebetween, which will be described hereinafter, and FIG. 4 shows a situation where no groove structure is arranged therebetween), a photoresist fully-reserved region A corresponding to a region of the active layer other than the groove structures, and a photoresist unreserved region C corresponding to a region other than a pattern of the active layer (i.e., a region not covered by the photoresist in FIG. 1). Step 14: as shown in FIG. 1D, the semiconductor material layer 4 corresponding to the photoresist unreserved region may be etched. Step 15: as shown in FIG. 1E, the photoresist 5 at the photoresist partially-reserved region B may be subjected to ashing treatment. Step 16: as shown in FIG. 1F, the semiconductor material layer 4 corresponding to the photoresist partially-region B may be etched to form the first groove structure 41 and the second groove structure 42. Step 17: as shown in FIG. 1G, the photoresist at the photoresist fully-reserved region may be subjected to ashing treatment to remove the remaining photoresist 5. Step 18: as shown in FIG. 1H, a metallic nanomaterial solution may be sprayed into the first groove structure 41 and the second groove structure 42 through ink-jet printing to form a first electrode 61 and a second electrode 62.

In a possible embodiment of the present disclosure, the metallic nanomaterial solution includes nanoparticles made of one or more selected from the group of Cu, Al, Ag, Mo, Cr, Nd, Ni, Mn, Ti, Ta and W.

According to the above-mentioned manufacture procedure of the TFT, the first electrode and the second electrode may be accurately formed in the first groove structure and the second groove structure through ink-jet printing. As compared with the conventional manufacture process, it is able to obviously improve the manufacture efficiency and reduce the manufacture cost. In addition, due to the ink-jet printing, it is unnecessary for the conductive material to fully cover the active layer to prevent the conductivity of the active layer from being adversely affected by the metallic ions of the conductive material, reduce the off-state current of the TFT, and enable a resultant display product to display an image stably.

It should be appreciated that, the above Steps 11 to 18 are merely for illustrative purposes. As mentioned above, referring to FIG. 1H, the method may further include forming a third groove structure 43 between the first groove structure 41 and the second groove structure 42. In other words, in FIG. 1D, the photoresist partially-reserved region B may further correspond to the third groove structure 43, so the semiconductor material layer 4 may be etched in Step 16 to from the third groove structure 43.

To be specific, the third groove structure 43 is an optional structure. In some embodiments of the present disclosure, it is also necessary to deposit ohmic contact layers 601, 602 onto the semiconductor material layer 4, so that the first electrode 61 and the second electrode 62 are in contact with the semiconductor material layer 4 through the ohmic contact layers 601, 602. Referring to FIG. 3, in the case that the ohmic contact layers are provided, it is necessary to etch off a portion of the ohmic contact layer between the first electrode 61 and the second electrode 62 through an etching process to form the third groove structure 43. The off-state current I_{off} of the TFT may be greatly affected by the conductivity of the active layer corresponding to the third groove structure 43, and through the method in the embodiments of the present disclosure, it is able to prevent the conductive material from being deposited onto the region where the third groove structure 43 is arranged. After the etching, it is able to form the ohmic contact layers 601, 602 corresponding to the first electrode 61 and the second electrode 62 respectively.

In addition, the method in the embodiments of the present disclosure may also be used to form the top-gate TFT. The principle thereof is identical to that mentioned above and thus will not be particularly defined herein.

The present disclosure further provides in some embodiments a TFT which, as shown in FIG. 1H, includes: an active layer 4* having a first groove structure 41 and a second groove structure 42, the first groove structure 41 and the second groove structure 42 being separated from each other; and a first electrode 61 at least partially within the first groove structure 41 and a second electrode 62 at least partially within the second groove structure 42.

The TFT may further include a third groove structure 43 arranged between the first groove structure 41 and the second groove structure 42. The third groove structure 43 is separated from the first groove structure 41 and the second groove structure 42. As mentioned above, through the third groove structure 43, it is able to effectively reduce the off-state current of the TFT, thereby to display an image stably.

Obviously, the TFT may be manufactured through the above-mentioned method, so a technical effect identical to that mentioned above may also be achieved.

The present disclosure further provides in some embodiments a method for manufacturing a display substrate, which includes the above-mentioned method for manufacturing the TFT of the display substrate. In addition, the method may further include steps of forming any other structures such as a liquid crystal layer and a color filter layer.

According to the method for manufacturing the display substrate in the embodiments of the present disclosure, on the basis of the above-mentioned method for manufacturing the TFT, it is able to simplify the manufacture process and reduce the manufacture cost, especially for a mass production scenario.

The present disclosure further provides in some embodiments a display substrate including the above-mentioned TFT and a display device including the display substrate. The display device may further include any other members such as a power first, a display assembly, a driving circuit and a control circuit.

Obviously, according to the display substrate and the display device in the embodiments of the present disclosure, on the basis of the above-mentioned TFT, it is able to display an image stably and improve the display quality thereof, thereby to improve the user experience.

To be specific, as shown in FIG. 2, in actual use, the display substrate may further include a passivation layer 7 covering the TFT and a pixel electrode 8. The pixel electrode 8 is connected to the second electrode of the TFT through a via-hole in the passivation layer 7 to receive a driving signal from the TFT.

In addition, the display device may be any product including the display substrate, i.e., it may be a display panel, a mobile phone, a PAD, a television or a vehicle-mounted screen.

The above are merely the preferred embodiments of the present disclosure, but the present disclosure is not limited thereto. Obviously, a person skilled in the art may make further modifications and improvements without departing from the spirit of the present disclosure, and these modifications and improvements shall also fall within the scope of the present disclosure.

What is claimed is:

1. A method for manufacturing a thin film transistor, comprising:
forming an active layer having a first groove structure and a second groove structure, the first groove structure and the second groove structure being separated from each other; and
depositing a conductive material into the first groove structure and the second groove structure to form a first electrode and a second electrode of the thin film transistor.

2. The method according to claim 1, wherein the step of forming the active layer having the first groove structure and the second groove structure comprises: depositing a semiconductor material layer; applying a photoresist onto the semiconductor material layer; exposing and developing the photoresist with a mask plate to form a photoresist partially-reserved region corresponding to the first groove structure and the second groove structure, a photoresist fully-reserved region corresponding to a region of the active layer other than the first groove structure and the second groove structure, and a photoresist unreserved region corresponding to a region other than a pattern of the active layer; etching the semiconductor material layer at the photoresist unreserved region; ashing the photoresist at the photoresist partially-reserved region, and etching the semiconductor material layer at the photoresist partially-reserved region to form the first groove structure and the second groove structure; and ashing the photoresist at the photoresist fully-reserved region.

3. The method according to claim 2, wherein a third groove structure is further arranged at a region corresponding to the photoresist partially-reserved region, and the method further comprises forming the third groove structure between the first groove structure and the second groove structure while forming the first groove structure and the second groove structure, the third groove structure being separated from the first groove structure and the second groove structure.

4. The method according to claim 1, wherein the step of depositing the conductive material into the first groove structure and the second groove structure comprises spraying a metallic nanomaterial solution into the first groove structure and the second groove structure through ink-jet printing to form the first electrode at least partially within the first groove structure and the second electrode at least partially within the second groove structure.

5. The method according to claim 4, wherein the metallic nanomaterial solution comprises nanoparticles made of one or more selected from the group of Cu, Al, Ag, Mo, Cr, Nd, Ni, Mn, Ti, Ta and W.

6. The method according to claim 1, wherein prior to the step of forming the active layer having the first groove structure and the second groove structure, the method further comprises forming a gate electrode and a gate insulation layer on a base substrate, and the active layer is formed on the gate insulation layer.

7. The method according to claim 1, wherein the first groove structure and the second groove structure are depressed in an identical direction and toward a base substrate of the thin film transistor.

8. A thin film transistor, comprising:
an active layer having a first groove structure and a second groove structure, the first groove structure and the second groove structure being separated from each other; and
a first electrode at least partially within the first groove structure and a second electrode at least partially within the second groove structure.

9. The TFT according to claim 8, wherein the active layer further comprises a third groove structure arranged between, and separated from, the first groove structure and the second groove structure.

10. A method for manufacturing a display substrate, comprising a method for manufacturing a thin film transistor, wherein the method for manufacturing a thin film transistor comprising:
forming an active layer having a first groove structure and a second groove structure, the first groove structure and the second groove structure being separated from each other; and
depositing a conductive material into the first groove structure and the second groove structure to form a first electrode and a second electrode of the thin film transistor.

11. A display substrate comprising the thin film transistor according to claim 8.

12. A display device comprising the display substrate according to claim 11.
